(19) United States
(12) Patent Application Publication
(10) Pub. No.: US 2024/0178311 A1
(43) Pub. Date: May 30, 2024

(54) High Frequency, High Temperature Transistor Devices

(71) Applicant: Wolfspeed, Inc., Durham, NC (US)

(72) Inventors: Kyle Bothe, Cary, NC (US); Satyaki Ganguly, Hillsborough, NC (US)

(21) Appl. No.: 18/071,768

(22) Filed: Nov. 30, 2022

(51) Int. Cl. H01L 29/778; H01L 29/40

(52) U.S. Cl. CPC H01L 29/7786; H01L 29/402

(57) ABSTRACT

Transistor devices are provided. In one example, a transistor device includes a Group III nitride-based semiconductor structure. The transistor device has a non-degradation time of at least about 350 hours without degrading an output power of the transistor device by 1 dB or greater during a test condition. The test condition is associated with an operating frequency of the transistor device of about 31.5 GHz and a junction temperature of the transistor device of about 380° ° C.

### FIELD

The present disclosure relates generally to transistor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

Power semiconductor devices may be fabricated from wide band gap semiconductor materials (e.g., having a band-gap greater than 1.40 eV). For example, power HEMTs may be fabricated from gallium nitride (GaN) or other Group III nitride-based material systems that are formed, for instance, on a silicon carbide (SiC) substrate or other substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide band gap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities as compared to gallium arsenide (GaAs) and silicon (Si) based devices.

### SUMMARY

Aspects and advantages of embodiments of the present disclosure will be set forth in part in the following description, or may be learned from the description, or may be learned through practice of the embodiments.

One example embodiment of the present disclosure is directed to a transistor device. The transistor device includes a Group III nitride-based semiconductor structure. The transistor device has a non-degradation time of at least about 350 hours without degrading an output power of the transistor device by 1 dB or greater during a test condition. The test condition is associated with an operating frequency of the transistor device of about 31.5 GHz and a junction temperature of the transistor device of about 380° C.

Another example embodiment of the present disclosure is directed to a transistor device. The transistor device includes a Group III nitride-based semiconductor structure. The transistor device has a non-degradation time of at least about 350 hours without degrading a gain of the transistor device by 1 dB or greater during a test condition. The test condition is associated with an operating frequency of about 31.5 GHz and a junction temperature of the transistor device of about 380° C.

Yet another example embodiment of the present disclosure is directed to a transistor device. The transistor device includes a Group III nitride-based semiconductor structure. The Group III nitride-based semiconductor structure includes a channel layer and a barrier layer on the channel layer. The barrier layer is associated with a first band gap. The channel layer is associated with a second band gap. The first band gap is different than the second band gap. The transistor device further includes a gate contact. The gate contact is associated with a gate length of about 150 nm or less. The transistor device includes a dielectric structure on the barrier layer. The dielectric structure has a thickness of about 3600 Angstroms or less.

Yet another example embodiment of the present disclosure is directed to a transistor device. The transistor device includes a Group III nitride-based semiconductor structure. The Group III nitride-based semiconductor structure includes a channel layer and a barrier layer on the channel layer. The barrier layer is associated with a first band gap. The channel layer is associated with a second band gap. The first band gap is different than the second band gap. The transistor device further includes a gate contact. The gate contact is associated with a gate length of about 150 nm or less. The transistor device further includes a dielectric structure on the barrier layer. The dielectric structure includes a first dielectric layer and a second dielectric layer. The first dielectric layer is between at least a portion of the gate contact and the Group III nitride-based semiconductor structure. The second dielectric layer is on the first dielectric layer. The first dielectric layer has a thickness of about 1450 Angstroms or less.

Yet another example embodiment of the present disclosure is directed to a transistor device. The transistor device includes a Group III nitride-based semiconductor structure. The Group III nitride-based semiconductor structure includes a channel layer and a barrier layer on the channel layer. The barrier layer is associated with a first band gap. The channel layer is associated with a second band gap. The first band gap is different than the second band gap. The transistor device further includes a gate contact. The gate contact is associated with a gate length of about 150 nm or less. The transistor device includes a field plate. A distance between the field plate and the Group III nitride-based semiconductor structure is about 3600 Angstroms or less.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a cross-sectional view of an example transistor device according to example embodiments of the present disclosure.

FIG. 2 depicts a cross-sectional view of an example semiconductor structure of a transistor device according to example embodiments of the present disclosure.

FIG. 3 depicts an example testing apparatus according to example embodiments of the present disclosure;

FIG. 4 depicts an example die containing transistor cells subject to a test condition according to example embodiments of the present disclosure;

FIG. 5 depicts example non-degradation time of an output power of a transistor device according to example embodiments of the present disclosure; and

FIG. 6 depicts example non-degradation time of a gain of a transistor device according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor devices may be used in power electronics applications. For instance, transistor devices, such as high electron mobility transistors (HEMTs), may be used in power electronics applications. HEMTs fabricated in Group III nitride-based material systems may have the potential to generate large amounts of radio frequency (RF) power because of the combination of material characteristics that includes high breakdown fields, wide band gaps, large conduction band offset, and/or high saturated electron drift velocity. As such, Group III nitride-based HEMTs may be promising candidates for high frequency and/or high-power RF applications (as well as for low frequency high power switching applications) as discrete transistors or as coupled with other circuit elements, such as in monolithic microwave integrated circuit (MMIC) devices.

Field effect transistors such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a two-dimensional electron gas (2DEG) is formed at the heterojunction of two semiconductor materials with different band gap energies, where the smaller band gap material has a higher electron affinity. The 2DEG is an accumulation layer in the smaller band gap material and may include a very high sheet electron concentration. Additionally, electrons that originate in the wider-band gap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

Many applications of HEMT devices are in the Ka band range (e.g., 26.5 GHz to 40 GHz). For instance, many applications of HEMT devices in aerospace, 5G and other radio frequency communication systems require operating frequencies of greater than about 30 GHz. Performance requirements for the HEMT devices may require operation of the HEMT devices at these high frequencies, and/or at high temperatures (e.g., junction temperatures greater than about 300° ° C., such as in a range of about 300° ° C. to about 420°) C., without degradation of output power and/or gain of the HEMT devices.

Aspects of the present disclosure are directed to Group III nitride-based transistor devices. The Group III nitride-based transistor devices may include a Group III nitride-based semiconductor structure. The Group III nitride-based semiconductor structure may include a Group III nitride-based channel layer and a Group III nitride-based barrier layer. For instance, the Group III nitride-based channel layer may be a GaN layer. The Group III nitride-based channel layer may be an AlGaN layer. A 2DEG may be formed at an interface between the Group III nitride-based channel layer and the Group III nitride-based barrier layer.

The transistor devices may have a source contact, a drain contact, and a gate contact. In some examples, the gate contact has a gate length. The gate length may be the length of a gate contact along the portion of the gate contact that is on the semiconductor structure. For operation at high frequencies, such as frequencies in the Ka band range, the gate length may be about 200 nm or less, such as about 150 nm or less, such as in a range of about 60 nm to about 200 nm, such as in a range of about 90 nm to about 150 nm.

The transistor devices may have a dielectric structure on the Group III nitride-based semiconductor structure. The dielectric structure may have one or more dielectric layers. In some examples, the dielectric structure may have a thickness of about 3600 Angstroms or less, such as a thickness in a range of about 3000 Angstroms to about 3600 Angstroms.

In some examples, the dielectric structure may include a first dielectric layer and a second dielectric layer. The first dielectric layer has a thickness of about 1450 Angstroms or less, such as in a range of about 800 Angstroms to about 1450 Angstroms. The first dielectric layer may be between the Group III nitride-based semiconductor structure and at least a portion of the gate contact. The dielectric structure, in some examples, may be silicon nitride (SiN) or other suitable dielectric material.

The transistor devices according to example embodiments of the present disclosure may provide technical effects and benefits. For instance, the present inventors have discovered that the transistor devices according to example embodiments of the present disclosure may demonstrate improved performance under high frequency and/or high temperature conditions.

For instance, in one example, the transistor device may be subject to a test condition. The test condition may apply an operating frequency for the transistor device of about 31.5 GHz. The test condition may apply a junction temperature Tj (e.g., temperature at the Group III nitride-based semiconductor structure) of about 380° C. The test condition may further include applying a drain voltage of about 28 V with a drain current of about 40 mA for the transistor device.

In some embodiments, the transistor device may have a non-degradation time of at least about 350 hours without degrading an output power of the transistor device by 1 dB or greater during the test condition. More particularly, the transistor device does not lose output power by 1 dB or greater when subject to the test condition for at least about 350 hours. In some examples, the transistor device may exhibit a non-degradation time of at least about 100 hours without degrading an output power of the transistor device by 0.5 dB or greater during the test condition. More particularly, the transistor device does not lose output power by 0.5 dB or greater when subject to the test condition for at least about 100 hours. The output power of the transistor device during the test condition may be about 20 dBm or greater. A power dissipation of the transistor device during the test condition may be about 4 W/mm or greater.

In some embodiments, the transistor device may have a non-degradation time of at least about 350 hours without degrading a gain of the transistor device by 1 dB or greater during the test condition. More particularly, the transistor device does not lose gain by 1 dB or greater when subject to the test condition for at least about 350 hours. In some embodiments, the transistor device may have a non-degradation time of at least about 100 hours without degrading a gain of the transistor device by 0.5 dB or greater during the test condition. More particularly, the transistor device does not lose output power by 0.5 dB or greater when subject to the test condition for at least about 100 hours.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other semiconductor devices without deviating from the scope of the present disclosure.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

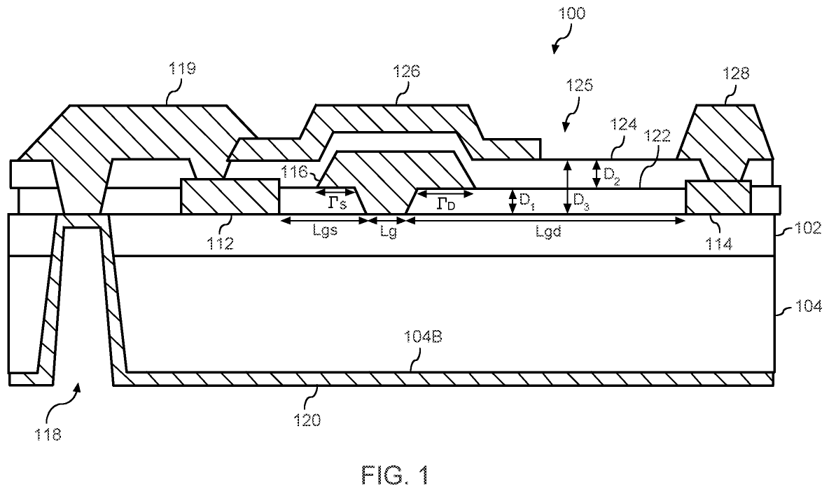

FIG. 1 depicts a cross-sectional view of an example HEMT device 100 according to example embodiments of the present disclosure. FIG. 1 is intended to represent structures for identification and description and is not intended to represent the structures to physical scale. The HEMT device 100 may include a semiconductor structure 102. The semiconductor structure 102 may be a Group III-nitride semiconductor structure.

As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements may combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements.

The semiconductor structure 102 may be on a substrate 104. The substrate 104 may be a semiconductor material. For instance, the substrate 104 may be a silicon substrate, a silicon carbide (SiC) substrate, a sapphire substrate, or other suitable substrate. In some embodiments, the substrate 104 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 104 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 104 may be a SiC wafer, and the HEMT device 100 may be formed, at least in part, via wafer-level processing, and the wafer may then be diced to provide a plurality of individual HEMT devices 100 that may include one or more transistor cells.

In some embodiments, the substrate 104 of the HEMT device 100 may be a thinned substrate 104. In some embodiments, the thickness of the substrate 104 (e.g., in a vertical Z direction in FIG. 1) may be about 100 μm or less, such as about 75 μm or less, such as about 50 μm or less.

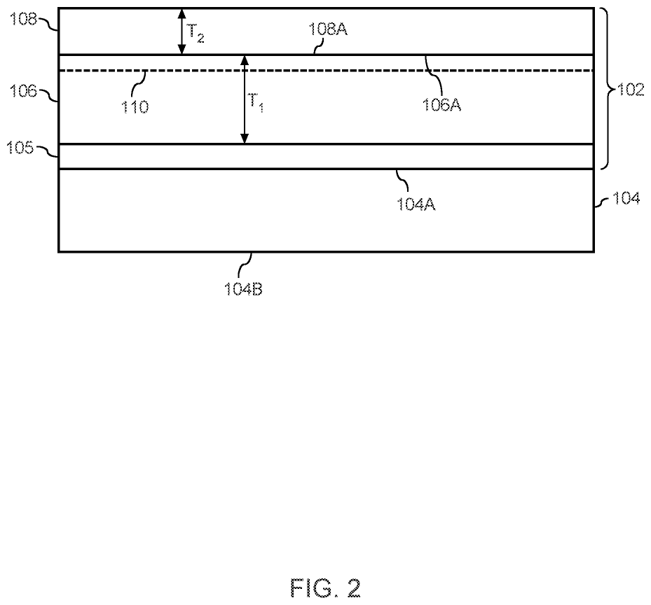

FIG. 2 depicts a cross-sectional view of the semiconductor structure on the substrate 104. The semiconductor structure 102 may include a channel layer 106 on an upper surface 104A of the substrate 104 (or on the optional layers described further herein, such as an optional buffer or nucleation layer 105). The semiconductor structure 102 may include a barrier layer 108 on an upper surface of the channel layer 106. In some embodiments, the channel layer 106 and the barrier layer 108 may each be formed by epitaxial growth. Techniques for epitaxial growth of Group III-nitrides have been described in, for example, U.S. Pat. Nos. 5,210,051, 5,393,993, and 5,523,589, the disclosures of which are incorporated by reference herein. The channel layer 106 may have a bandgap that is less than the bandgap of the barrier layer 108. The channel layer 106 may have a larger electron affinity than the barrier layer 108. The channel layer 106 and the barrier layer 108 may include Group III nitride-based materials.

In some embodiments, the channel layer 106 may be a Group III-nitride, such as AlₓGa₁₋ₓN, where 0≤x<0.11, provided that the energy of the conduction band edge of the channel layer 106 is less than the energy of the conduction band edge of the barrier layer 108 at the interface between the channel layer 106 and barrier layer 108. In some embodiments, the aluminum mole fraction x is approximately 0 (e.g., less than 5%, such as 0%), indicating that the channel layer 106 is GaN. The channel layer 106 may or may not include other Group III-nitrides such as InGaN, AlInGaN or the like. The channel layer 106 may be undoped (“unintentionally doped”). In some examples, the channel layer 106 may be doped, for instance with iron (Fe). The channel layer 106 may have a thickness T₁ of about 0.5 μm to about 5 μm, such as about 1.4 μm. The channel layer 106 may be a multi-layer structure, such as a superlattice or combinations of GaN, AlGaN or the like. The channel layer 106 may be under compressive strain in some embodiments.

The barrier layer 108 includes a Group III nitride-based layer having a surface 108A positioned on a surface 106A of the channel layer 106. The barrier layer 108 may be a Group III-nitride, such as Al_{y}Ga_{1-y}N, where y is the aluminum mole fraction in the barrier layer 108. The energy of the conduction band edge of the barrier layer 108 is greater than the energy of the conduction band edge of the channel layer 106 at the interface between the channel layer 106 and barrier layer 108. In some embodiments, the aluminum mole fraction y is such that y is in a range of about 0.15 to about 0.30, such as about 0.20 to about 0.25, such as about 0.22 (e.g., the aluminum mole fraction is in a range of 15% to 30%, such as in a range of about 20% to about 25%, such as about 22%), indicating that the barrier layer is an AlGaN layer. The barrier layer 108 may include other Group III elements (e.g., In) without deviating from the scope of the present disclosure. The barrier layer 108, in some examples, may be a multilayer structure. The multilayer structure may include multiple Group III nitride-based layers with differing aluminum mole fractions. The barrier layer 108 may have a thickness T₂. The thickness T₂ may be in a range of about 10 Angstroms to about 300 Angstroms, such as about 120 Angstroms to about 170 Angstroms, such as about 150 Angstroms. The channel layer 106 and/or the barrier layer 108 may be deposited, for example, by metal-organic chemical vapor deposition (MOCVD), molecular beam epitaxy (MBE), or hydride vapor phase epitaxy (HVPE).

A 2DEG 110 may be induced in the channel layer 106 at an interface between the channel layer 106 and the barrier layer 108. The 2DEG 110 is highly conductive and allows conduction between the source and drain regions of the HEMT device 100.

While the HEMT device 100 of FIGS. 1-2 is shown with a substrate 104, channel layer 106 and barrier layer 108 for purposes of illustration, the HEMT device 100 may include additional layers/structures/elements. For instance, the HEMT device 100 may include a buffer layer(s)/nucleation layer(s)/transition layer(s) 105 between substrate 104 and the channel layer 106. For example, an AlN buffer layer may be on the upper surface 104A of the substrate 104 to provide an appropriate crystal structure transition between a SiC substrate 104 and the channel layer 106. The optional buffer/nucleation/transition layers 105 may be deposited by MOCVD, MBE, and/or HYPE.

The HEMT device 100 may include a cap layer (not illustrated) on the barrier layer 108. HEMT structures including substrates, channel layers, barrier layers, and other layers are discussed by way of example in U.S. Pat. Nos. 5,192,987, 5,296,395, 6,316,793, 6,548,333, 7,544,963, 7,548,112, 7,592,211, 7,615,774, 7,709,269, 7,709,859 and 10,971,612, the disclosures of which are incorporated by reference herein. Additionally, strain balancing transition layer(s) may also and/or alternatively be provided as described, for example, in U.S. Pat. No. 7,030,428, the disclosure of which is incorporated by reference herein.

Referring to FIG. 1, the HEMT device 100 may include a source contact 112 on the semiconductor structure 102 or otherwise contacting the semiconductor structure 102. The HEMT device 100 may include a drain contact 114 on the semiconductor structure 102 or otherwise contacting the semiconductor structure 102. The source contact 112 and the drain contact 114 may be laterally spaced apart from each other. In some embodiments, the source contact 112 and the drain contact 114 may include a metal that may form an ohmic contact to a Group III nitride-based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), nickel (Ni), gold (Au), aluminum (Al), tantalum (Ta), molybdenum (Mo), NiSiₓ, titanium silicide (TiSi), titanium nitride (TiN), tungsten silicon nitride (WsiN), platinum (Pt) and the like. In some embodiments, the source contact 112 may be an ohmic source contact 112. The drain contact 114 may be an ohmic drain contact 114. Thus, the source contact 112 and/or the drain contact 114 may include an ohmic contact portion in direct contact with the barrier layer 108. In some embodiments, the source contact 112 and/or the drain contact 114 may include a plurality of layers to form an ohmic contact that may be provided as described, for example, in U.S. Pat. Nos. 8,563,372 and 9,214,352, the disclosures of which are incorporated by reference herein.

The HEMT device 100 may include a gate contact 116 on the semiconductor structure 102 or otherwise contacting the semiconductor structure 102 (e.g., at least partially recessed into the semiconductor structure 102). The gate contact 116 may have a gate length L_{G}. The gate length L_{G} may be the length of the gate contact 116 along the portion of the gate contact 116 that is on the semiconductor structure 102 (e.g., the length of the lowermost portion of the gate contact 116 in contact with the semiconductor structure 102). In some embodiments, the gate length L_{G} may be about 200 nm or less, such as about 150 nm or less, such as in a range of about 60 nm to about 200 nm, such as in a range of about 90 nm to about 150 nm. A distance Lgd between the gate contact 116 and the drain contact 114 may be, for instance, in a range of 1.8 μm to about 2.2 μm, such as about 1.98 μm. A distance Lgs between the gate contact 116 and the source contact 112 may be, for instance, in a range of about 0.4 μm to about 0.8 μm, such as about 0.6 μm.

The material of the gate contact 116 may be chosen based on the composition of the barrier layer 108, and may, in some embodiments, be a Schottky contact. Materials capable of making a Schottky contact to a Group III nitride-based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN).

In some embodiments, the gate contact 116 may be a T-shaped gate and/or a gamma gate, the formation of which is discussed by way of example in U.S. Pat. Nos. 8,049,252, 7,045,404, and 8,120,064, the disclosures of which are incorporated by reference herein. The gate contact 116 may have an overhang toward the drain contact 114. The length Γ_{D} of the overhang toward the drain contact 114 may be in a range of about 0.15 μm to about 0.25 μm, such as about 0.2 μm. The gate contact 116 may have an overhang toward the source contact 112. The length Γ_{S of the overhang} toward the source contact 112 may be in a range of about 0.15 μm to about 0.25 μm, such as about 0.2 μm.

The source contact 112 may be coupled to a reference signal such as, for example, a ground voltage or other reference signal. The coupling to the reference signal may be provided by a via 118 that extends from a lower surface 104B of the substrate 104, through the substrate 104 and semiconductor structure 102 to the upper surface of the semiconductor structure 102. The via 118 may be coupled to a metal contact 119. The metal contact 119 may include metal or other highly conductive material, including, for example, copper, cobalt, gold, and/or a composite metal. The metal contact 119 may conductively couple the via 118 to the source contact 112. A back metal layer 120 may be on the lower surface 104B of the substrate 104 and on side walls of the via 118. The back metal layer 120 may be conductively coupled to the metal contact 119. Thus, the back metal layer 120, and a signal coupled thereto, may be electrically connected to the source contact 112 through the metal contact 119.

In some embodiments, the via 118 may have an oval or circular cross-section when viewed in a plan view. However, the present disclosure is not limited thereto. In some embodiments, a cross-section of the via 118 may be a polygon or other shape, as will be understood by one of ordinary skill in the art using the disclosures provided herein. In some embodiments, dimensions of the via (e.g., a length and/or a width) may be such that a largest cross-sectional area of the via 118 is about 1000 μm² or less. The cross-sectional area may be taken in a direction that is parallel to the lower surface 104B of the substrate 104 (e.g., the X-Y plane of FIG. 1). In some embodiments, the largest cross-sectional area of the via 118 may be that portion of the via 118 that is adjacent the lower surface 104B of the substrate 104 (e.g., the opening of the via 118). For example, in some embodiments, a greatest width (e.g., in the X direction in FIG. 1) may be about 16 μm and a greatest length (e.g., in the Y direction in FIG. 1) may be about 40 μm, though the present disclosure is not limited thereto. In some embodiments, sidewalls of the via 118 may be inclined and/or slanted with respect to the lower surface 104B of the substrate 104. In some embodiments, the sidewalls of the via 118 may be approximately perpendicular to the lower surface 104B of the substrate 104.

Depending on the embodiment, the drain contact 114 may be formed on, in and/or through the semiconductor structure 102, and there may be ion implantation into the materials around the drain contact 114 to reduce resistivity and provide improved ohmic contact to the semiconductor material. In yet other embodiments, there is no source via 118, and the source contact 112 is formed on, in and/or through the semiconductor structure 102, and there may be ion implantation in the materials around the source contact 112 to reduce resistivity and provide improved ohmic contact to the semiconductor material. Where there is no source via 118, the electrical connections to the source contact 112 may be made on the same side as the gate contact 116 and the drain contact 114. In some examples, the connections to the source contact 112, drain contact 114, and/or gate contact 116 may be made from the top and/or the bottom to provide for flip chip configuration of the HEMT device 100. In some examples, thermal paths may be provided from the top and/or bottom to provide for flip chip configuration of the HEMT device 100.

The HEMT device 100 may include a dielectric structure 125 on the semiconductor structure 102. The dielectric structure 125 may include a first dielectric layer 122 and a second dielectric layer. The first dielectric layer 122 may directly contact the upper surface of the semiconductor structure 102. At least a portion of the first dielectric layer 122 may be between the semiconductor structure 102 and at least a portion of the gate contact 116. For instance, at least a portion of the first dielectric layer 122 may be between the semiconductor structure 102 and the overhang of the gate contact 116. The first dielectric layer 122 may have a thickness D₁. In some embodiments, the thickness D₁ of the first dielectric layer 122 may be about 1450 Angstroms or less, such as in a range of about 800 Angstroms to about 1450 Angstroms, such as about 1200 Angstroms. In this way, the overhang of the T-shaped or Gamma-shaped gate contact 116 may be separated from the semiconductor structure 102 by a distance approximately equal to D₁. The first dielectric layer 122 may be a SiN layer. Other suitable dielectric materials may be used without deviating from the scope of the present disclosure. For instance, the first dielectric layer 122 may be SiO₂, Si, Ge, MgOx, MgNx, ZnO, SiNx, SiOx, alloys or layer sequences thereof, or epitaxial materials.

The dielectric structure 125 may include a second dielectric layer 124 on the first dielectric layer 122. The second dielectric layer 124 may be the same dielectric material or a different dielectric material relative to the first dielectric layer 122. For instance, the second dielectric layer may be a SiN layer. Other suitable dielectric materials may be used without deviating from the scope of the present disclosure. For instance, the second dielectric layer 124 may be SiO₂, Si, Ge, MgOx, MgNx, ZnO, SiNx, SiOx, alloys or layer sequences thereof, or epitaxial materials. The second dielectric layer 124 may have a thickness D₂. In some embodiments, the thickness D₂ of the second dielectric layer 124 may be about 2800 Angstroms or less, such as in a range of about 1500 Angstroms to about 2800 Angstroms, such as about 2100 Angstroms.

The dielectric structure 125 may have a thickness D₃. In some embodiments, the thickness D₃ of the dielectric structure may be about 3600 Angstroms or less, such as in a range of about 3000 Angstroms to about 3600 Angstroms, such as about 3300 Angstroms.

One or more field plates 126 may be on the dielectric structure 125 as illustrated in FIG. 1. At least a portion of a field plate 126 may be overlapping the gate contact 116. At least a portion of the field plate 126 may be on a portion of the second dielectric layer 124. In some embodiments, the field plate 126 may be conductively coupled to the gate contact 116. The field plate 126 may reduce the peak electric field in the HEMT device 100, which may result in increased breakdown voltage and reduced charge trapping. The reduction of the electric field may also yield other benefits such as reduced leakage currents and enhanced reliability. Field plates and techniques for forming field plates are discussed, by way of example, in U.S. Pat. No. 8,120,064, the disclosure of which is incorporated by reference herein.

The field plate 126 may be separated from the semiconductor structure by a distance approximately equal to D₃. The distance D₃ may increase the effectiveness of the field plate 126 in reducing the electric field in the semiconductor structure 102, leading to higher electron mobility in the 2DEG 110 and increased performance of the HEMT device 100.

Moreover, the decrease in D₁ and in D₃ of the HEMT device 100 may lead to a reduction in drain-gate capacitance and/or gate-source capacitance of the HEMT device 100. This may be particularly true in embodiments where the field plate 126 is conductively coupled to the gate contact 116. The reduction in drain-gate capacitance and/or gate-source capacitance of the HEMT device 100 may lead to improved performance of the HEMT device 100 at high frequency conditions (e.g., 30 GHz or greater)

Metal contacts 119 and 128 may be in the dielectric structure 125 as illustrated in FIG. 1. The metal contacts 119 and 128 may provide interconnection between the source contact 112, drain contact 114, gate contact 116, and other parts of the HEMT device 100. Metal contact 119 may be conductively coupled to the source contact 112. Metal contact 128 may be conductively coupled to the drain contact 114. The metal contacts 119 and 128 may include metal or other highly conductive material, including, for example, copper, cobalt, gold, and/or a composite metal.

A HEMT transistor cell may be formed by the active region between the source contact 112 and the drain contact 114 under the control of the gate contact 116 between the source contact 112 and the drain contact 114. FIG. 1 depicts a cross-sectional view of one unit or cell of an HEMT device 100 for purposes of illustration. The HEMT device unit or cell may be formed adjacent to additional HEMT device cells and may share, for instance, a source contact 112 with adjacent HEMT device cells. The HEMT device 100 may be formed, at least in part, via wafer-level processing, and the wafer may then be diced to provide a plurality of individual HEMT devices 100.

In some embodiments, the HEMT device(s) 100 according to example embodiments of the present disclosure exhibit increased non-degradation time under high frequency and high temperature conditions. To demonstrate the enhanced performance of the HEMT device(s) 100 according to example embodiments of the present disclosure, the HEMT device(s) 100 may be subject to a test condition.

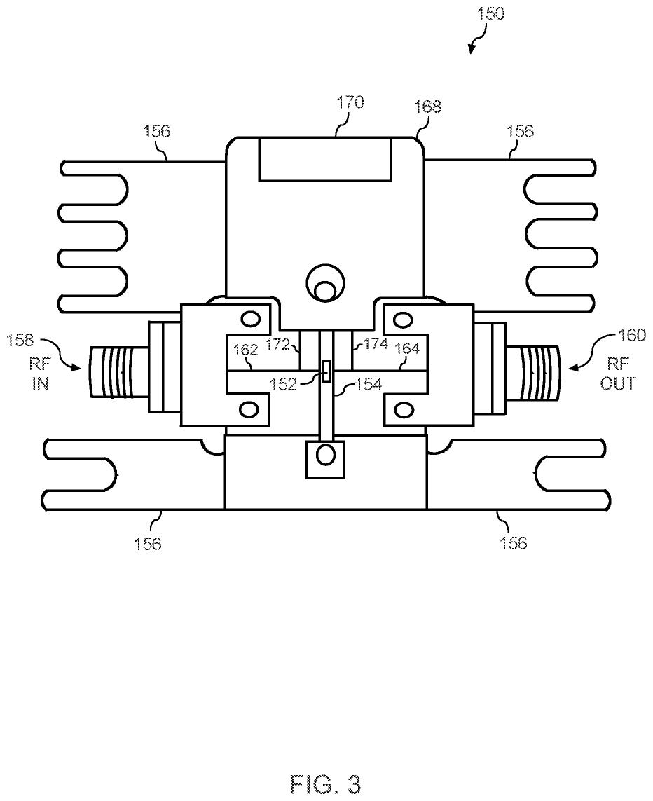

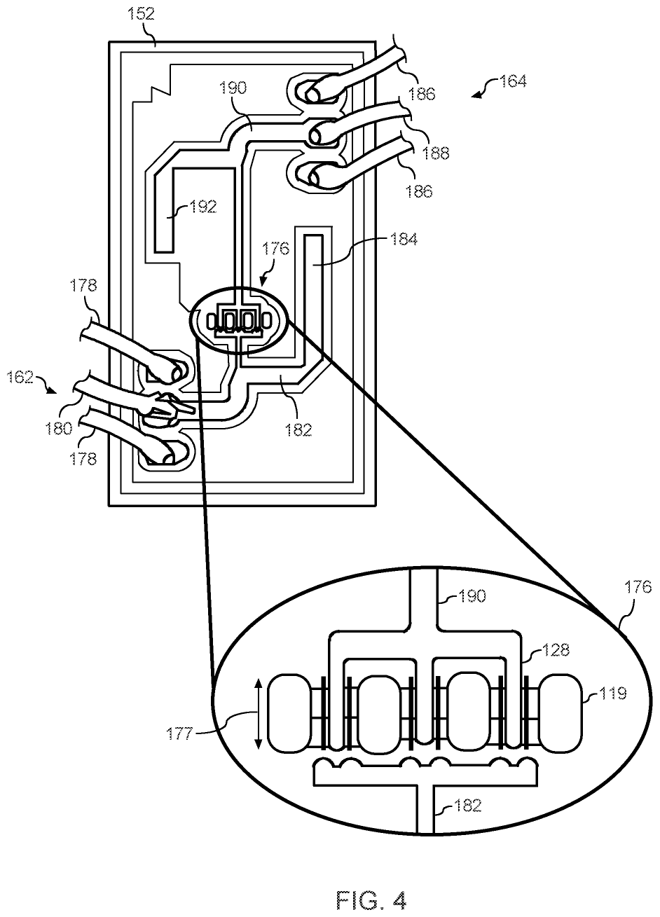

FIG. 3 depicts an example test apparatus 150 for applying a test condition to transistor devices according to example embodiments of the present disclosure. In the test apparatus 150, a die 152 having a transistor device with one or more transistor cells according to example embodiments of the present disclosure may be mounted to a base plate or thermal bus 154. Details concerning the die 152 will be discussed with reference to FIG. 4. Referring to FIG. 3, the thermal bus 154 may be operable to transfer heat to the die 152 to raise a junction temperature Tj of the one or more transistor cells on the die 152 to a test temperature. The test temperature may be, for instance, about 380° C.

The thermal bus 154 may be coupled to thermal sinks 156 through thermally conductive paths and connections. The thermal sinks 156 may couple the thermal bus 154 to a heat source (not shown) to regulate the temperature of the thermal bus 154 to transfer heat to the die 152 such that the junction temperature of the Tj of the transistor cells on the die 152 is at the test temperature (e.g., about 380)° ° C. The junction temperature Tj of the transistor cells on the die 152 may be estimated to be at the same temperature of the thermal bus 154 or may be determined using an algorithm, look up table, or function correlating the junction temperature Tj of the transistor cells on the die 152 to the temperature of the thermal bus 154. The junction temperature Tj of the transistors on the die 152 may be regulated to be at the test temperature by controlling the temperature of the thermal bus 154. For instance, the junction temperature Tj may be controlled to be about 380° C. by controlling the temperature of the thermal bus 154 to be about 180° C. In this regard, the test condition may include maintaining the temperature of the thermal bus 154 to be about 180° C.

The test apparatus 150 may include an RF input 158 and an RF output 160. The RF input 158 may be coupled to the die 152 with a transmission line 162 (e.g., one or more traces), wire bonds, and/or other connections. The RF output 160 may be coupled to the die 152 with a transmission line 164 (e.g., one or more traces) wire bonds, and/or other connections. The test apparatus 150 may apply a signal to, for instance, the transistor cells on the die 152. The signal may be associated with a test operating frequency. The test operating frequency may be, for instance, about 31.5 GHz.

The test apparatus 150 may include a circuit board 168. The circuit board 168 may include a connector 170. The connector 170 may receive power (e.g., DC power) and/or may communicate signals (e.g., control signals, temperature measurement signals indicative of the temperature of the thermal bus 154, or other signals). The circuit board 168 may include circuit elements (e.g., one or more resistors, capacitors or other circuit elements). The circuit board 168 may provide a DC bias, through a signal path 172, to the transmission line 164. The circuit board 168 may provide, for instance, a DC bias, through a signal path 174, to the transmission line 164.

FIG. 4 depicts the die 152 having a plurality of transistor cells 176 according to example embodiments of the present disclosure. Each of the transistor cells 176 may have a cross-section corresponding to the transistor device 100 illustrated in FIGS. 1-2. The die 152 has six transistor cells 176. More or fewer transistor cells may be included without deviating from the scope of the present disclosure. Each transistor cell 176 shares a source contact (beneath metal contact 119 in FIG. 4) with an adjacent transistor cell 176. Each transistor cell 176 shares a drain contact (beneath metal contact 128 in FIG. 4) with an adjacent transistor cell 176. Each of the transistor cells 176 may have a gate finger (not shown) acting as the gate contact for the transistor cell 176. The gate finger may be associated with a gate finger length. The gate finger length may be representative of the length of the gate contacts in the direction indicated by dimension 177 in FIG. 4. In some examples, the gate finger length may be about 100 μm or less, such as about 50 μm.

As shown, the die 152 may be connected to the transmission line 162 through wire bonds 178 and 180. Wire bonds 178 may be coupled to a ground or other reference signal associated with the transmission line 162. The wire bonds 178 may be coupled through conductive paths (not shown) to the source contacts of the transistor cells 176. Wire bond 180 may be coupled to an input signal. Wire bond 180 may be coupled to gate contacts of the transistor cells 176 via gate path 182. The gate path 182 may have a tuning stub 184 for impedance matching (e.g., 50-ohm impedance matching). The input signal may have a test frequency of about 31.5 GHz.

The die 152 may be connected to the transmission line 164 through wire bonds 186 and 188. Wire bonds 186 may be coupled to a ground or other reference signal. The wire bonds 186 may be coupled through conductive paths (not shown) to the source contacts of the transistor cells 176. Wire bond 186 may be coupled to an output signal. Wire bond 180 may be coupled to the drain contacts of the transistor cells 176 via a drain path 190. The drain path 190 may have tuning stub 192 for impedance matching (e.g., 50-ohm impedance matching). The output signal may be associated with the test frequency of about 31.5 GHz.

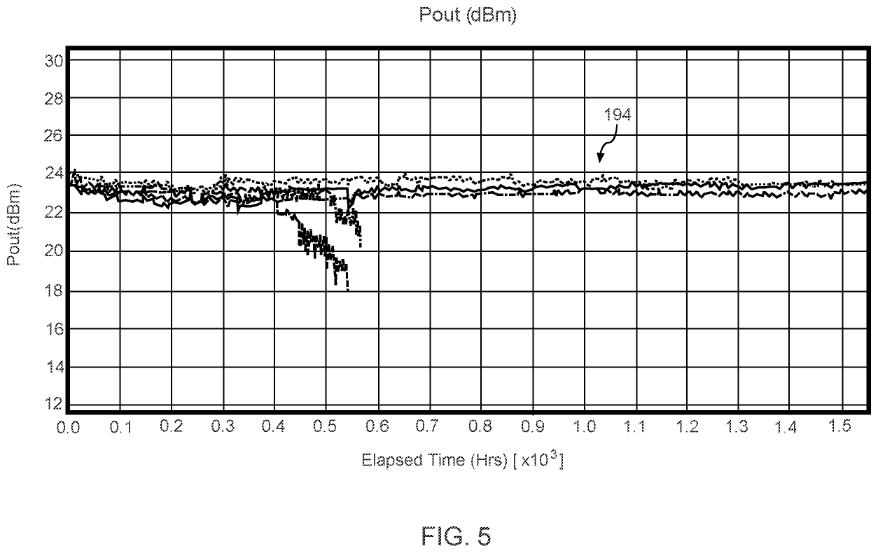

FIG. 5 depicts example non-degradation times of transistor devices subject to a test condition (e.g., using test apparatus 150 of FIG. 3). FIG. 5 plots output power (dBm) on the vertical axis and elapsed time under the test condition (hours) along the horizontal axis. Each of the curves 194 is associated with a different transistor device. Each transistor device may correspond to the HEMT device 100 discussed with reference to FIGS. 1 and 2.

The test condition may apply a signal associated with an operating frequency of about 31.5 GHz to the transistor device. The test condition may include maintaining a junction temperature Tj of the transistor device at about 380° C. during the test condition. The test condition may include applying a 28 V drain voltage to the transistor device during the test condition. The transistor device may have a drain current of about 40 mA during the test condition. The power dissipation of the transistor device during the test condition may be about 4 W/mm or greater.

As demonstrated by the curves 194 in FIG. 5, the transistor devices have a non-degradation time of at least about 350 hours, such as at least about 400 hours, without degrading an output power of the transistor device by 1 dB or greater during the test condition. The transistor devices have a non-degradation time of at least about 100 hours without degrading the output power of the transistor device by 0.5 dB. The output power of the transistor device during the test condition be about 20 dBm or greater, such as about 22 dBm or greater, such as about 24 dBm or greater, such as in a range of about 22 dBM to 24 dBm.

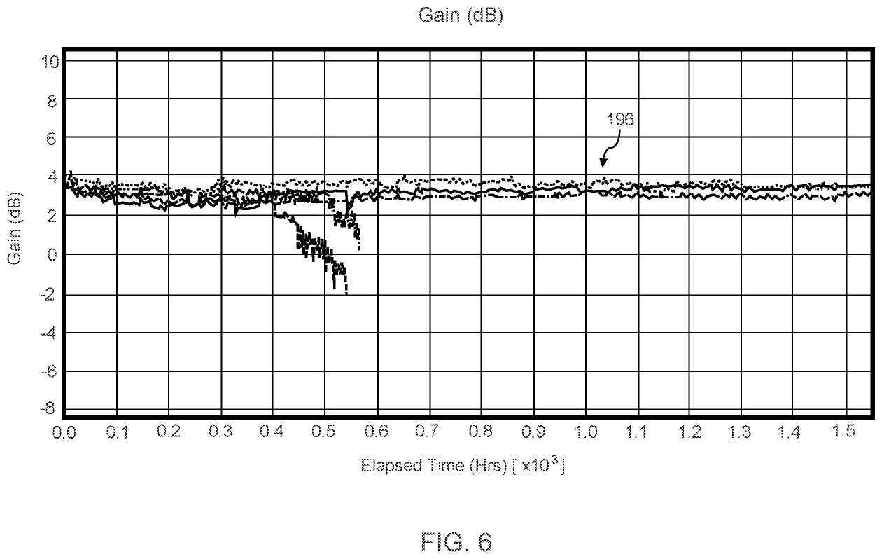

FIG. 6 depicts example non-degradation times of transistor devices subject to a test condition (e.g., using test apparatus 150 of FIG. 3). FIG. 6 plots gain (dB) on the vertical axis and elapsed time under the test condition (hours) along the horizontal axis. Each of the curves 196 is associated with a different transistor device. Each transistor device may correspond to the HEMT device 100 discussed with reference to FIGS. 1 and 2.

The test condition may apply a signal associated with an operating frequency of about 31.5 GHz to the transistor device. The test condition may include maintaining a junction temperature Tj of the transistor device at about 380° C. during the test condition. The test condition may include applying a 28 V drain voltage to the transistor device during the test condition. The transistor device may have a drain current of about 40 mA during the test condition. The power dissipation of the transistor device during the test condition may be about 4 W/mm or greater.

As demonstrated by the curves 196 in FIG. 6, the transistor devices have a non-degradation time of at least about 350 hours, such as at least about 400 hours, without degrading a gain of the transistor device by 1 dB or greater during the test condition. The transistor devices have a non-degradation time of at least about 100 hours without degrading the gain of the transistor device by 0.5 dB. The gain of the transistor device during the test condition be about 2 dB or greater, such as in a range of about 2 dB to about 4 dB.

Example aspects of the present disclosure are provided in the following paragraphs, the example of which may be combined to form various different embodiments of the present disclosure.

One example embodiment of the present disclosure is directed to a transistor device. The transistor device includes a Group III nitride-based semiconductor structure. The transistor device has a non-degradation time of at least about 350 hours without degrading an output power of the transistor device by 1 dB or greater during a test condition. The test condition is associated with an operating frequency of the transistor device of about 31.5 GHz and a junction temperature of the transistor device of about 380° C.

Another example embodiment of the present disclosure is directed to a transistor device. The transistor device includes a Group III nitride-based semiconductor structure. The transistor device has a non-degradation time of at least about 350 hours without degrading a gain of the transistor device by 1 dB or greater during a test condition. The test condition is associated with an operating frequency of about 31.5 GHz and a junction temperature of the transistor device of about 380° C.

Some examples are directed to the transistor device of any preceding paragraph, wherein the test condition is associated with a drain voltage of about 28V for the transistor device and a drain current of about 40 mA for the transistor device.

Some examples are directed to the transistor device of any preceding paragraph, wherein the transistor device has a non-degradation time of at least about 350 hours without degrading a gain of the transistor device by 1 dB or greater during the test condition.

Some examples are directed to the transistor device of any preceding paragraph, wherein the transistor device has a non-degradation time of at least about 100 hours without degrading the output power of the transistor device by 0.5 dB or greater during the test condition.

Some examples are directed to the transistor device of any preceding paragraph, wherein the transistor device has a non-degradation time of at least about 100 hours without degrading a gain by about 0.5 dB or greater during the test condition.

Some examples are directed to the transistor device of any preceding paragraph, wherein the output power of the transistor device during the test condition is about 20 dBm or greater.

Some examples are directed to the transistor device of any preceding paragraph, wherein a power dissipation of the transistor device during the test condition is about 4 W/mm or greater.

Some examples are directed to the transistor device of any preceding paragraph, wherein the transistor device further includes a gate contact. The gate contact is associated with a gate length of about 200 nm or less. In some examples, the gate contact is associated with a gate length of about 150 nm or less.

Some examples are directed to the transistor device of any preceding paragraph, wherein the transistor further includes a gate contact. The gate contact is associated with a gate finger length of about 100 μm or less.

Some examples are directed to the transistor device of any preceding paragraph, wherein the transistor device includes a dielectric structure including one or more dielectric layers on the Group III nitride-based semiconductor structure. The dielectric structure has a thickness of about 3600 Angstroms or less. In some examples, a thickness of the dielectric structure is in a range of about 3000 Angstroms to about 3600 Angstroms.

Some examples are directed to the transistor device of any preceding paragraph, wherein the dielectric structure includes a first dielectric layer and a second dielectric layer. The first dielectric layer has a thickness of about 1450 Angstroms or less. In some examples, a thickness of the first dielectric layer is in a range of about 800 Angstroms to about 1450 Angstroms.

Some examples are directed to a transistor device of any preceding paragraph, wherein the first dielectric layer is between the Group III nitride-based semiconductor structure and at least a portion of a gate contact.

Some examples are directed to a transistor device of any preceding paragraph, wherein the dielectric structure includes silicon nitride.

Some examples are directed to a transistor device of any preceding paragraph, wherein the Group III nitride-based semiconductor structure includes a Group III nitride-based channel layer and a Group III nitride-based barrier layer. In some examples, the Group III nitride-based channel layer comprises AlxGa1−xN and the Group III nitride-based barrier layer comprises AlyGa1−yN, where x is in a range between 0 and 0.1 and y is in a range of about 0.15 to about 0.30.

Some examples are directed to a transistor device of any preceding paragraph, wherein the transistor device further includes a field plate. In some embodiments, a distance between the field plate and the Group III nitride-based semiconductor structure is about 3600 Angstroms or less.

Some examples are directed to a transistor device of any preceding paragraph, wherein the Group III nitride-based semiconductor structure is on a silicon carbide substrate.

Some examples are directed to a transistor device of any preceding paragraph, wherein the transistor device is a high electron mobility transistor device.

Yet another example embodiment of the present disclosure is directed to a transistor device. The transistor device includes a Group III nitride-based semiconductor structure. The Group III nitride-based semiconductor structure includes a channel layer and a barrier layer on the channel layer. The barrier layer is associated with a first band gap. The channel layer is associated with a second band gap. The first band gap is different than the second band gap. The transistor device further includes a gate contact. The gate contact is associated with a gate length of about 150 nm or less. The transistor device includes a dielectric structure on the barrier layer. The dielectric structure has a thickness of about 3600 Angstroms or less.

Some examples are directed to a transistor device of any preceding paragraph, wherein the transistor device has a non-degradation time of at least about 350 hours without degrading an output power of the transistor device by 1 dB or greater during a test condition. The test condition is associated an operating frequency of the transistor device of about 31.5 GHz and a junction temperature of the transistor device of about 380° C. The test condition applies a drain voltage of about 28V and a drain current of about 40 mA to the transistor device.

Some examples are directed to a transistor device of any preceding paragraph, wherein the transistor device has a non-degradation time of at least about 350 hours without degrading a gain of the transistor device by 1 dB or greater during a test condition. The test condition is associated an operating frequency of the transistor device of about 31.5 GHz and a junction temperature of the transistor device of about 380° C. The test condition applies a drain voltage of about 28V and a drain current of about 40 mA to the transistor device.

Some examples are directed to a transistor device of any preceding paragraph, wherein a thickness of the dielectric structure is in a range of about 3000 Angstrom to about 3600 Angstroms.

Some examples are directed to a transistor device of any preceding paragraph, wherein the dielectric structure comprises a first dielectric layer and a second dielectric layer. The first dielectric layer is between at least a portion of the gate contact and the Group III nitride-based semiconductor structure. The second dielectric layer is on the first dielectric layer.

Some examples are directed to a transistor device of any preceding paragraph, wherein the first dielectric layer has a thickness of about 1450 Angstroms or less. In some examples, a thickness of the first dielectric layer is in a range of about 800 Angstroms to about 1450 Angstroms.

Some examples are directed to a transistor device of any preceding paragraph, wherein the dielectric structure comprises silicon nitride.

Yet another example embodiment of the present disclosure is directed to a transistor device. The transistor device includes a Group III nitride-based semiconductor structure. The Group III nitride-based semiconductor structure includes a channel layer and a barrier layer on the channel layer. The barrier layer is associated with a first band gap. The channel layer is associated with a second band gap. The first band gap is different than the second band gap. The transistor device further includes a gate contact. The gate contact is associated with a gate length of about 150 nm or less. The transistor device further includes a dielectric structure on the barrier layer. The dielectric structure includes a first dielectric layer and a second dielectric layer. The first dielectric layer is between at least a portion of the gate contact and the Group III nitride-based semiconductor structure. The second dielectric layer is on the first dielectric layer. The first dielectric layer has a thickness of about 1450 Angstroms or less.

Some examples are directed to a transistor device of any preceding paragraph, wherein the transistor device has a non-degradation time of at least about 350 hours without degrading an output power of the transistor device by 1 dB or greater during a test condition. The test condition is associated an operating frequency of the transistor device of about 31.5 GHz and a junction temperature of the transistor device of about 380° C. The test condition applies a drain voltage of about 28V and a drain current of about 40 mA to the transistor device.

Some examples are directed to a transistor device of any preceding paragraph, wherein the transistor device has a non-degradation time of at least about 350 hours without degrading a gain of the transistor device by 1 dB or greater during a test condition. The test condition is associated an operating frequency of the transistor device of about 31.5 GHz and a junction temperature of the transistor device of about 380° C. The test condition applies a drain voltage of about 28V and a drain current of about 40 mA to the transistor device.

Some examples are directed to a transistor device of any preceding paragraph, wherein a thickness of the first dielectric layer is in a range of about 800 Angstroms to about 1450 Angstroms.

Some examples are directed to a transistor device of any preceding paragraph, wherein the dielectric structure comprises silicon nitride.

Yet another example embodiment of the present disclosure is directed to a transistor device. The transistor device includes a Group III nitride-based semiconductor structure. The Group III nitride-based semiconductor structure includes a channel layer and a barrier layer on the channel layer. The barrier layer is associated with a first band gap. The channel layer is associated with a second band gap. The first band gap is different than the second band gap. The transistor device further includes a gate contact. The gate contact is associated with a gate length of about 150 nm or less. The transistor device includes a field plate. A distance between the field plate and the Group III nitride-based semiconductor structure is about 3600 Angstroms or less.

Some examples are directed to a transistor device of any preceding paragraph, wherein the transistor device includes a dielectric structure on the barrier layer. In some examples, a thickness of the dielectric structure is in a range of about 3000 Angstrom to about 3600 Angstroms.

Some examples are directed to a transistor device of any preceding paragraph, wherein the dielectric structure comprises a first dielectric layer and a second dielectric layer. The second dielectric layer is on the first dielectric layer.

Some examples are directed to a transistor device of any preceding paragraph, wherein the first dielectric layer has a thickness of about 1450 Angstroms or less. In some examples, a thickness of the first dielectric layer is in a range of about 800 Angstroms to about 1450 Angstroms.

Some examples are directed to a transistor device of any preceding paragraph, wherein the first dielectric layer is between the semiconductor structure and at least a portion of a gate contact.

Some examples are directed to a transistor device of any preceding paragraph, wherein the field plate is on the dielectric structure.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A transistor device, comprising:
a Group III nitride-based semiconductor structure;
wherein the transistor device has a non-degradation time of at least about 350 hours without degrading an output power of the transistor device by 1 dB or greater during a test condition, the test condition associated with an operating frequency of the transistor device of about 31.5 GHz and a junction temperature of the transistor device of about 380° C.

2. The transistor device of claim 1, wherein the test condition is associated with a drain voltage of about 28V for the transistor device and a drain current of about 40 mA for the transistor device.

3. The transistor device of claim 1, wherein the transistor device has a non-degradation time of at least about 350 hours without degrading a gain of the transistor device by 1 dB or greater during the test condition.

4. The transistor device of claim 1, wherein the transistor device has a non-degradation time of at least about 100 hours without degrading the output power of the transistor device by 0.5 dB or greater during the test condition.

5. The transistor device of claim 1, wherein the transistor device has a non-degradation time of at least about 100 hours without degrading a gain by about 0.5 dB or greater during the test condition.

6. The transistor device of claim 1, wherein the output power of the transistor device during the test condition is about 20 dBm or greater.

7. The transistor device of claim 1, wherein a power dissipation of the transistor device during the test condition is about 4 W/mm or greater.

8. The transistor device of claim 1, further comprising a gate contact, the gate contact associated with a gate length of about 200 nm or less.

9. (canceled)

10. (canceled)

11. The transistor device of claim 1, further comprising a dielectric structure comprising one or more dielectric layers on the Group III nitride-based semiconductor structure, the dielectric structure having a thickness of about 3600 Angstroms or less.

12. (canceled)

13. The transistor device of claim 11, wherein the dielectric structure comprises a first dielectric layer and a second dielectric layer, wherein the first dielectric layer has a thickness of about 1450 Angstroms or less.

14. (canceled)

15. The transistor device of claim 13, wherein the first dielectric layer is between the Group III nitride-based semiconductor structure and at least a portion of a gate contact.

16. The transistor device of claim 11, wherein the dielectric structure comprises silicon nitride.

17. The transistor device of claim 1, wherein the Group III nitride-based semiconductor structure comprises a Group III nitride-based channel layer and a Group III nitride-based barrier layer.

18. The transistor device of claim 17, wherein the Group III nitride-based channel layer comprises AlₓGa₁₋ₓN and the Group III nitride-based barrier layer comprises Al_{y}Ga_{1-y}N, where x is in a range between 0 and 0.1 and y is in a range of about 0.15 to about 0.30.

19. The transistor device of claim 1, further comprising a field plate.

20. The transistor device of claim 19, wherein a distance between the field plate and the Group III nitride-based semiconductor structure is about 3600 Angstroms or less.

21. The transistor device of claim 1, wherein the Group III nitride-based semiconductor structure is on a silicon carbide substrate.

22. The transistor device of claim 1, wherein the transistor device is a high electron mobility transistor device.

23. A transistor device, comprising:
a Group III nitride-based semiconductor structure;
wherein the transistor device has a non-degradation time of at least about 350 hours without degrading a gain of the transistor device by 1 dB or greater during a test condition, the test condition associated with an operating frequency of about 31.5 GHz and a junction temperature of the transistor device of about 380° C.

24.-42. (canceled)

43. A transistor device, comprising:
a Group III nitride-based semiconductor structure, the Group III nitride-based semiconductor structure comprising a channel layer and a barrier layer on the channel layer, the barrier layer associated with a first band gap, the channel layer associated with a second band gap, the first band gap being different than the second band gap;
a gate contact, the gate contact associated with a gate length of about 150 nm or less; and
a dielectric structure on the barrier layer;
wherein the dielectric structure has a thickness of about 3600 Angstroms or less.

44.-62. (canceled)
